(19) United States
(12) Patent Application Publication
(10) Pub. No.: US 2009/0321775 A1
(43) Pub. Date: Dec. 31, 2009

(54) LED with Reduced Electrode Area

(76) Inventor: Ghulam Hasnain, Palo Alto, CA (US)

Correspondence Address: THE LAW OFFICES OF CALVIN B. WARD, 18 CROW CANYON COURT, SUITE 305, SAN RAMON, CA, 94583, US

(21) Appl. No.: 12/147,242

(22) Filed: Jun. 26, 2008

(51) Int. Cl. H01L 33/00

(52) U.S. Cl. 257/99; 438/22; 257/E33.064

(57) ABSTRACT

A light source and method for fabricating the same are disclosed. The light source includes a substrate and first and second semiconductor layers that surround an active layer. The first layer includes a material of a first conductivity type adjacent to the substrate. The active layer overlies the first layer and generates light when holes and electrons recombine therein. The second layer includes a material of a second conductivity type overlying the active layer, the second layer having a first surface overlying the active layer and a second surface opposite to the first surface. A trench extends through the second layer and the active layer into the first layer. The trench has electrically insulating walls. A first electrode is disposed in the trench such that the first electrode is in electrical contact with the first layer, and the second electrode is in electrical contact with the second layer.

### BACKGROUND OF THE INVENTION

Light emitting devices (LEDs) are an important class of solid-state devices that convert electric energy to light. Improvements in these devices have resulted in their use in light fixtures designed to replace conventional incandescent and fluorescent light sources. The LEDs have significantly longer lifetimes and, in some cases, significantly higher efficiency for converting electric energy to light.

The cost per lumen of light generated is an important factor in determining the rate at which this new technology will replace conventional light sources. For any given material system, the light generated per unit area of surface on the LED has a maximum value that is determined by thermal factors such as heat dissipation and the maximum temperature at which the LED can operate. As the LED temperature rises, the efficiency of light conversion decreases. The cost of the LED is proportional to the area of the die on which the LED is fabricated. Since there is a maximum light output per unit area of LED surface, any region of the die that does not generate light increases the cost per lumen of the LED.

An LED can be viewed as a three-layer structure formed on a substrate in which an active layer that generates the light is sandwiched between a p-layer and an n-layer. Power is applied through contacts on the p-layer and n-layer that spread the current over the layers in question. Typically, the n-layer is adjacent to the substrate, and the p-layer is the uppermost layer. Current spreading over the p-layer can be facilitated by an electrode structure that covers the surface of the p-layer. In the case of an LED that emits light through the p-layer, the electrode structure can include a transparent layer such as ITO.

The contact to the n-layer is formed in a trench that is etched through the p-layer and active layer. To provide sufficient current spreading area, the surface area devoted to this trench must be a significant fraction of the surface area of the LED. The size of this trench is increased further to accommodate the alignment tolerances of the fabrication process. The trenched area does not generate light. Hence, this trench is a significant factor in the cost per lumen of the LED.

### SUMMARY OF THE INVENTION

The present invention includes a light source and method for fabricating the same. The light source includes a substrate, and first and second semiconductor layers that surround an active layer. The first layer includes a material of a first conductivity type adjacent to the substrate. The active layer overlies the first layer and generates light when holes and electrons recombine therein. The second layer includes a material of a second conductivity type overlying the active layer, the second layer having a first surface overlying the active layer and a second surface opposite to the first surface. A trench extends through the second layer and the active layer into the first layer. The trench has electrically insulating walls. A first electrode is disposed in the trench such that the first electrode is in electrical contact with the first layer, and the second electrode is in electrical contact with the second layer. In one aspect of the invention, the electrically insulating walls comprise a layer of SiN. In another aspect of the invention, the first electrode includes a layer of metal that fills the trench and is in contact with the insulating walls. In a further aspect of the invention, a layer of transparent electrically conducting material is disposed between the second electrode and the second surface. In a still further aspect of the invention, an electrical insulator underlies the second electrical contact and is disposed between the second layer of transparent electrically conducting material and the second surface. The insulating material is the same as the insulating layer that is present on the walls of the trench.

### BRIEF DESCRIPTION OF THE DRAWINGS

FIG. 1 is a top view of a prior art LED 20.

FIG. 2 is a cross-sectional view of LED 20 through line 2-2 shown in FIG. 1.

FIG. 3 is a cross-sectional view of an LED according to one aspect of the present invention.

FIGS. 4-6 are cross-sectional views of the fabrication of an LED 50 according to one aspect of the present invention.

### DETAILED DESCRIPTION OF THE PREFERRED EMBODIMENTS OF THE INVENTION

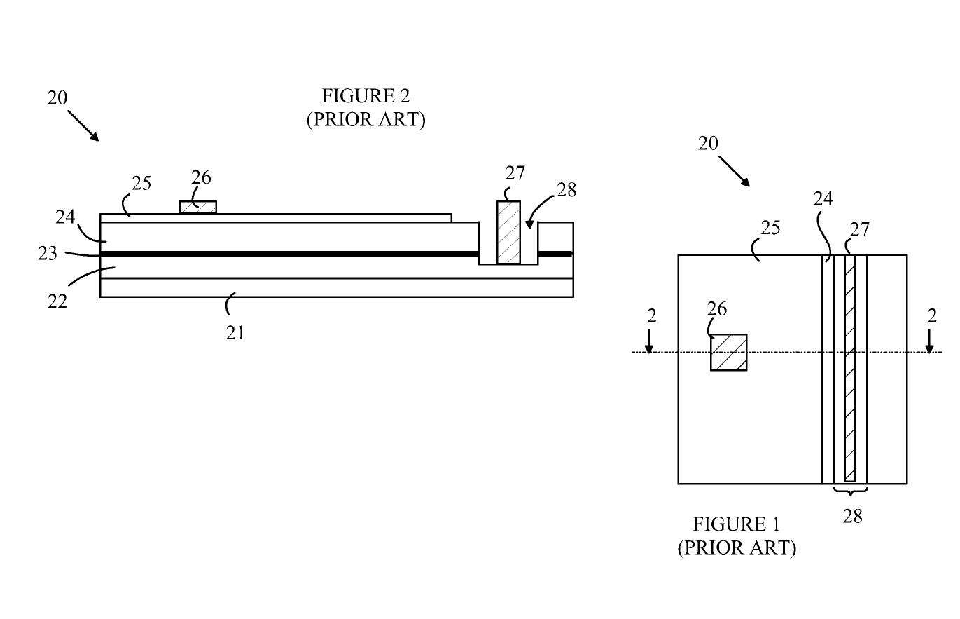

The manner in which the present invention provides its advantages can be more easily understood with reference to FIGS. 1 and 2, which illustrate a prior art LED. FIG. 1 is a top view of LED 20, and FIG. 2 is a cross-sectional view of LED 20 through line 2-2 shown in FIG. 1. LED 20 is constructed on a substrate 21 by depositing a number of layers on substrate 21. LED 20 can be viewed as having three layers consisting of an n-type layer 22, an active layer 23, and a p-type layer 24. Each of these layers includes a number of sub-layers; however, since the sub-layers are not relevant to the present invention, the sub-layers have been omitted from the drawings to simplify the drawings.

Active layer 23 generates light when holes and electrons combine therein in response to a potential difference being created across layers 22 and 24. The potential difference is created by connecting contacts 26 and 27 to a power source. The resistivity of the p-layer is typically too large to provide adequate current spreading across the p-layer, and hence, a transparent electrode 25 is deposited between contact 26 and layer 24 to facilitate current spreading.

To provide access to the layer 22, a trench 28 is etched through layers 23 and 24 and into layer 22. Contact 27 is then deposited in trench 28. To provide adequate current spreading, the trench extends across LED 20. In larger LEDs, there may be multiple trenches. Hence the trench area can be a significant fraction of the light emitting area of the LED. Since the portion of the LED that has been trenched does not generate any light, the trench area is wasted from the point of view of light generation, and hence, increases the cost per lumen of the LED.

In prior art designs, the area of the trench is significantly greater than the area covered by contact 27. It is of critical importance that contact 27 is not electrically connected to either layers 23 or 24, since the resulting short circuit would render the LED inoperative. In prior art LED fabrication systems, contact 27 is deposited directly into trench 28. To assure that no contact is formed when the metal layer is deposited in the trench, the trench is made significantly wider than contact 27 to accommodate alignment errors during the fabrication process. In subsequent fabrication steps, the area between contact 27 and the walls of the trench is filled with an insulating material as part of the process of encapsulating the LED to prevent moisture and other environmental contaminants from attacking these layers. Since contact 27 is not in contact with the walls of trench 28, the quality of the insulating material is not critical. For example, a pinhole in the insulating material will not lead to a short.

The present invention overcomes the shorting problem by lining the trench with an insulating material that is pinhole free and then depositing the contact material into the lined trench. The thickness of the trench lining is much less than the air gap utilized in the fabrication schemes discussed above, and hence, the area lost to the trench is substantially reduced. The masking operation needed to provide the trench lining can be combined with another masking operation that is used to further improve the current conversion efficiency of the LED, and hence, the cost of the additional deposition step is minimal.

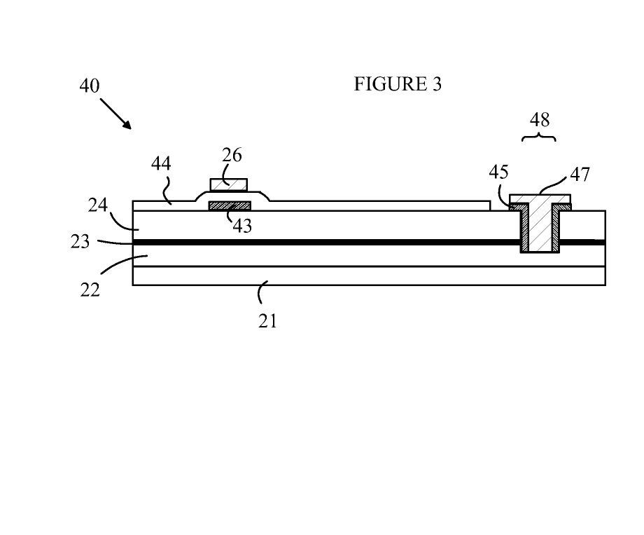

Refer now to FIG. 3, which is a cross-sectional view of an LED according to one aspect of the present invention. LED 40 can also be viewed as having three layers consisting of an n-type layer 22, an active layer 23, and a p-type layer 24. Prior to depositing transparent electrode 44, a trench 48 is etched through layers 23 and 24 and into layer 22. A patterned layer of SiN is then deposited to generate an insulating island 43 under contact 26 and to insulate the walls of trench 48 as shown at 45. The insulating layer 45 prevents contact 47 from shorting to layers 23 and 24. The width of trench 48 is typically 10 μm and the thickness of layer 45 is typically 100 nm. In prior art devices, the trench is typically 30 μm. Hence, the present invention provides a substantial reduction in the area needed for the trench.

Insulating island 43 essentially blocks the current that flows through the active layer directly under contact 26. In general, contact 26 is opaque and partially absorbing, and hence, a significant fraction of the light generated in the region directly under contact 26 is lost. Hence, in the absence of island 43, a substantial fraction of the current passing through the region under contact 26 would be wasted resulting in a loss in efficiency as measured by the light output per watt of power consumed. In addition, the wasted current generates heat that must be removed. Island 26 prevents this loss, and hence, increases the power conversion efficiency of LED 40 and reduces the heat generated by the LED per lumen of light leaving LED 40. In prior art designs that utilize an island such as island 43, the island is constructed from thin PECVD SiOx. However, SiOx is not a suitable dielectric for insulating the walls of trench 48, since pinholes are common in thin SiOx dielectric layers.

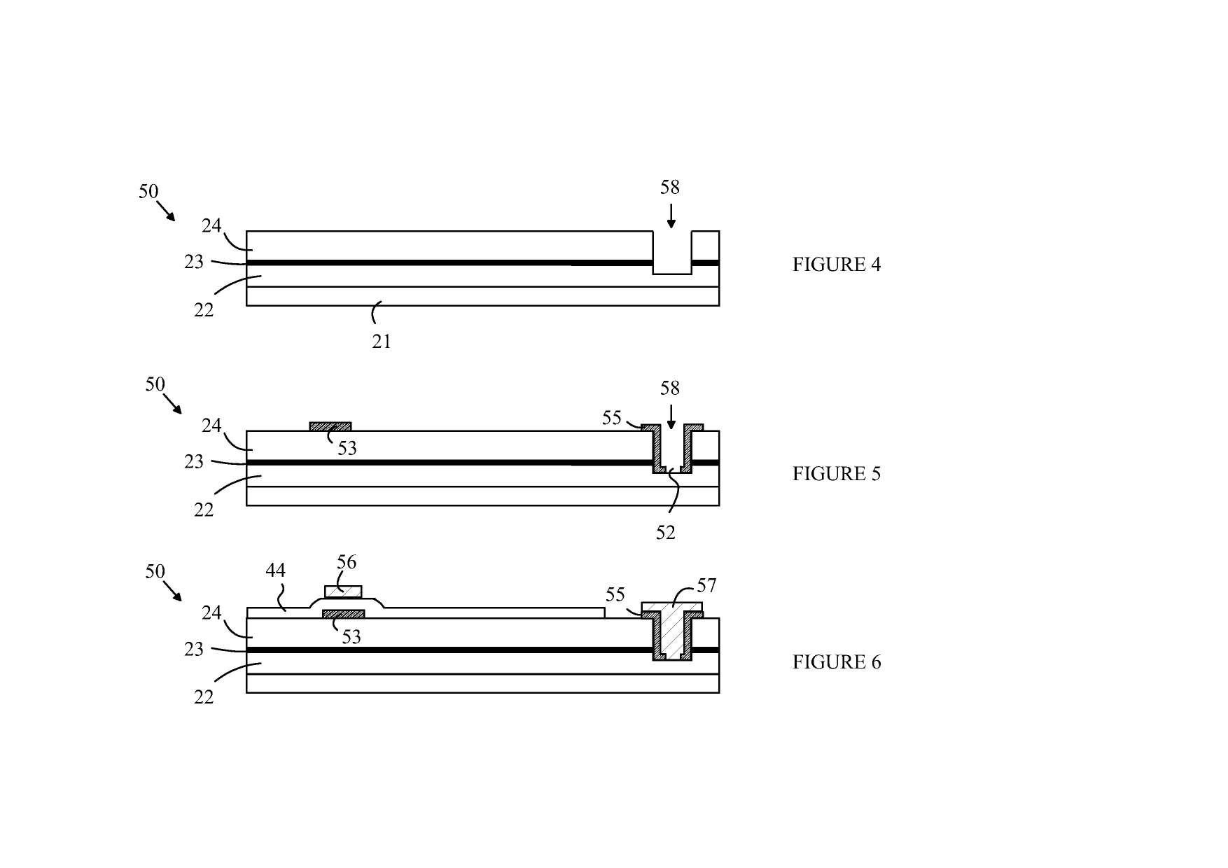

The manner in which LED 40 is fabricated can be more easily understood with reference to FIGS. 4-6, which are cross-sectional views of the fabrication of an LED 50 according to one aspect of the present invention. Referring to FIG. 4, layers 22-24 are deposited on substrate 21 as described above. A trench 58 is then etched through layers 23 and 24 and into layer 22. Referring to FIG. 5, a patterned SiN layer is then deposited to form island 53 and an insulating layer 55 on the walls of trench 58. The bottom 52 of layer 55 is etched to provide electrical access to layer 22. Next, current spreading layer 44 is deposited and patterned over island 53 while protecting trench 58. Finally, a patterned metal layer is deposited to form contacts 56 and 57 as shown in FIG. 6.

The above-described LEDs according to the present invention utilize a current blocking island such as island 53 discussed above. However, LEDs according to the present invention that lack this feature can also be constructed. This feature is obtained at little cost from the same layer that is used to insulate the trench walls, and hence, is particularly attractive in LEDs according to the present invention.

The above-described LEDs according to the present invention utilize SiN as the insulating material for the trench walls. This material is particularly attractive in that it can be deposited in a thin layer without pinholes that would cause shorts between contact 57 and layers 23 or 24. However, other insulating materials could be utilized. For example, AlNx, TiOx, AlOx, or SiOxNy could be utilized.

The above-described LEDs according to the present invention emit light from the top surface of the LED, and hence, utilize a transparent current spreading layer. However, embodiments which emit light through the bottom surface of the substrate can also be constructed. In this case, the current spreading layer on the top surface can also be a reflecting surface that redirects light leaving the top surface of the LED toward the substrate. Such embodiments do not benefit from the insulating island under the electrical contact, and hence, would lack that insulating island.

The LEDs described above utilize a configuration in which the n-type layer is deposited on the substrate and the p-type layer is deposited last. However, LEDs according to the present invention in which the p-type layer is deposited first can also be constructed.

Various modifications to the present invention will become apparent to those skilled in the art from the foregoing description and accompanying drawings. Accordingly, the present invention is to be limited solely by the scope of the following claims.

1. A light source comprising:
a substrate;
a first layer comprising a material of a first conductivity type adjacent to said substrate;
an active layer overlying said first layer, said active layer generating light when holes and electrons recombine therein;
a second layer comprising a material of a second conductivity type overlying said active layer, said second layer having a first surface overlying said active layer and a second surface opposite to said first surface;
a trench extending through said second layer and said active layer into said first layer, said trench having electrically insulating walls;
a first electrode disposed in said trench such that said first electrode is in electrical contact with said first layer; and
a second electrode in electrical contact with said second layer.
wherein said light source is fabricated in a fabrication process characterized by an alignment tolerance that specifies a magnitude of alignment errors in depositing said first electrode in said trench and wherein said insulating walls have a thickness less than said alignment errors.

2. The light source of claim 1 wherein said electrically insulating walls comprise a layer of SiN.

3. The light source of claim 1 wherein said first electrode comprises a layer of metal that fills said trench and is in contact with said insulating walls.

4. The light source of claim 1 further comprising a layer of transparent electrically conducting material between said second electrode and said second surface.

5. The light source of claim 4 further comprising an electrical insulator underlying said second electrical contact and disposed between said layer of transparent electrically conducting material and said second surface.

6. The light source of claim 5 wherein said electrically insulating walls comprise a layer of an insulating material and said insulator comprises the same insulating material.

7. The light source of claim 6 wherein said insulating material is chosen from the group consisting of SiN, AlNx, TiOx, AlOx, and SiOxNy.

8. A method for fabricating a light emitting device, said method comprising:
depositing a first layer comprising a material of a first conductivity type adjacent to a substrate;
depositing an active layer overlying said first layer, said active layer generating light when holes and electrons recombine therein;
depositing a second layer comprising a material of a second conductivity type overlying said active layer, said second layer having a first surface overlying said active layer and a second surface opposite to said first surface;
etching a trench extending through said second layer and said active layer into said first layer;
depositing an insulating material in said trench;
etching a hole in said insulating layer in a portion of said insulating layer to expose a portion of said first layer with said trench; and
depositing a layer of conducting material in said trench to form a first contact that is electrically connected to said first layer.

9. The method of claim 8 further comprising depositing said insulating material on said second surface at the same time that said insulating layer is deposited into said trench and patterning said insulating material to form an island of insulating material adjacent to said second surface.

10. The method of claim 9 further comprising depositing a transparent layer of electrically conducting material over said island and said second surface and then depositing a patterned layer of electrically conducting material over said island to form a second contact that is electrically connected to said transparent layer.
